(19) United States
(12) Patent Application Publication
(10) Pub. No.: US 2016/0284937 A1
(43) Pub. Date: Sep. 29, 2016

(54) LED ELEMENT

(71) Applicant: USHIO DENKI KABUSHIKI KAISHA, Tokyo (JP)

(72) Inventors: Kohei MIYOSHI, Hyogo (JP); Masashi TSUKIHARA, Hyogo (JP); Toru SUGIYAMA, Hyogo (JP)

(73) Assignee: USHIO DENKI KABUSHIKI KAISHA, Tokyo (JP)

(21) Appl. No.: 14/777,687

(22) PCT Filed: Mar. 19, 2014
(86) PCT No.: PCT/JP2014/057505

§ 371 Date: Sep. 16, 2015

(30) Foreign Application Priority Data
Mar. 21, 2013 (JP) 2013-058662

(51) Int. Cl. H01L 33/14; H01L 33/38; H01L 33/32; H01L 33/42; H01L 33/06; H01L 33/02

(52) U.S. Cl. CPC H01L 33/14; H01L 33/06; H01L 33/025; H01L 33/32; H01L 33/42; H01L 33/38

(57) ABSTRACT

Provided is an LED element which achieves a high light extraction efficiency even at a low operation voltage and which can be manufactured by means of a simple process. The LED element has: a first semiconductor layer constituted of n-type nitride semiconductor; a light emitting layer constituted of nitride semiconductor; a second semiconductor layer formed on top of the light emitting layer and constituted of p-type nitride semiconductor; a first electrode constituted of a transparent electrode where a bottom surface thereof is in contact with a portion of an upper surface of the first semiconductor layer; and a second electrode formed on top of the second semiconductor layer. At least a region of the first semiconductor layer, which region is in contact with the first electrode, is constituted of AlₙGa₁₋ₙN (0<n≦1) and has an n-type impurity concentration larger than 1×1019/cm³.

### TECHNICAL FIELD

The present invention relates to an LED element, and more particularly to a lateral-type LED element constituted of nitride semiconductor.

### BACKGROUND ART

Conventionally, in an LED element using nitride semiconductor, GaN is mainly used. In this case, the LED element made of nitride semiconductor is formed by forming a GaN film with few defects by epitaxially growing on a sapphire substrate from the viewpoint of lattice matching. Here, the sapphire substrate is an insulating material. Therefore, for power supply to a GaN-based LED element, the n-layer is exposed by cutting a part of the p-layer, and an electrode for power supply is formed on each of the p-layer and the n-layer. An LED element having a structure in which the electrodes for power supply are arranged in the same direction in this manner is referred to as lateral-type structure, and such a technique is disclosed, for example, in the following Patent Document 1.

Also, the following Patent Document 2 discloses a construction in which the light extraction efficiency is enhanced by using a transparent electrode (light-transmitting electroconductive layer) such as ITO as the P-side electrode.

### PRIOR ART DOCUMENTS

### Patent Documents

Patent Document 1: JP-B1-2976951
Patent Document 2: JP-B1-5045248
Patent Document 3: JP-A-2007-258529

### Non-Patent Document

Non-patent Document 1: S. Fritze, et al., “High Si and Ge n-type doping of GaN doping—Limits and impact on stress”, Applied Physics Letters 100, 122104, (2012)

### SUMMARY OF THE INVENTION

### Problems to be Solved by the Invention

FIG. 11A is a sectional model view of an LED element disclosed in the above Patent Document 2. The LED element 90 includes a support substrate 11, an undoped semiconductor layer 13, an n-type semiconductor layer 61, a light emitting layer 17, a p-type semiconductor layer 19, a first electrode 63, a second electrode 23, a power supply terminal 25, and a power supply terminal 27.

Further, the first electrode 63 functioning as an n-side electrode is constituted of a metal electrode, and the second electrode 23 functioning as a p-side electrode is constituted of a transparent electrode. Here, an n-type GaN layer is used as the n-type semiconductor layer 61, and a p-type GaN layer is used as the p-type semiconductor layer 19. The n-type semiconductor layer 61, the light emitting layer 17, and the p-type semiconductor layer 19 constitute an LED layer 50. Also, a sapphire substrate is used as the support substrate 11, and an undoped GaN layer is used as the undoped semiconductor layer 13.

In the following, the n-type semiconductor layer 61 will be referred to as “n-type GaN layer 61”; the first electrode 63 will be referred to as “metal electrode 63”; and the second electrode 23 will be referred to as “transparent electrode 23” for the sake of description.

When a voltage is applied between the power supply terminal 25 and the power supply terminal 27, an electric current flows from the power supply terminal 27 toward the power supply terminal 25 via the transparent electrode 23, the p-type semiconductor layer 19, the light emitting layer 17, the n-type GaN layer 61, and the metal electrode 63 in this order. During this period, a region of the light emitting layer 17 is let to emit light by the electric current flowing through the light emitting layer 17. This light is extracted in an upward direction (in the direction of an arrow symbol d1) on a paper sheet by being transmitted through the transparent electrode 23.

In the meantime, the light generated in the light emitting layer 17 not only goes upward, but some of the light is radiated downward, that is, toward the support substrate 11 side. In order to enhance the light extraction efficiency, a construction may be conceived in which a reflection electrode 14 is disposed on a bottom surface of the support substrate 11 so as to let the light be reflected upward by the reflection electrode 14 (See FIG. 11B).

Among the light reflected at the reflection electrode 14, the light propagating toward the transparent electrode 23 side is directly transmitted through this transparent electrode 23 to be extracted to the outside. However, some of the light reflected at the reflection electrode 14 propagates toward the metal electrode 63. However, since the metal electrode 63 does not have a light-transmitting property, the light propagating in this direction is absorbed by the metal electrode 63, so that the light cannot be efficiently extracted to the outside.

Here, if a transparent electrode can be formed as the n-side electrode in place of the metal electrode 63, the light reflected from the reflection electrode 14 and propagating toward the n-side electrode also can be extracted to the outside, so that this is effective in improving the light extraction efficiency. However, due to later-described reasons, there is a problem in that, in the construction shown in FIG. 11B, the metal electrode 63 cannot be simply replaced with a transparent electrode.

A transparent electrode has a larger specific resistance than a metal, so that it is difficult to establish an ohmic connection at the interface between the transparent electrode and the n-type GaN layer 61. As a result of this, a large resistance is generated between the n-type GaN layer 61 and the transparent electrode functioning as the n-side electrode, thereby raising a need to apply a large voltage between the p-side electrode and the n-side electrode in order to allow the electric current needed for light emission to flow through the light emitting layer.

In order to let the needed electric current flow through the light emitting layer while suppressing the applied voltage needed for light emission, it is preferable to reduce the resistance value between the p-side electrode and the n-side electrode as much as possible. Thus, in order to reduce the resistance value between the n-type GaN layer 61 and the n-side electrode as much as possible while adopting a transparent electrode as the n-side electrode, there can be conceived a method of achieving an ohmic connection between the n-type GaN layer 61 and the n-side electrode by increasing the amount of doping the n-type GaN layer 61 with an n-type impurity as much as possible.

In the meantime, with respect to the n-type GaN layer 61 constituting the n-type semiconductor layer among the semiconductor layers constituting the LED layer 50, there is known a phenomenon such that, when the doping amount of the n-type GaN layer 61 is increased to be 1×10¹⁹/cm³ or more, a film roughening is generated due to aggravation of the atomic bonding state or the like (See, for example, the above Non-patent Document 1). When such a phenomenon occurs, an n-layer having a low resistance is not formed, and eventually the light emission efficiency decreases.

In order to overcome this problem, the above Patent Document 3 adopts a construction in which an n-layer having a high concentration and an n-layer having a low concentration are successively alternately stacked. According to this Patent Document 3, it is assumed that, by adopting such a construction, the surface roughening formed on the high-concentration layer is covered with the low-concentration layer, whereby an n-layer having a good quality is formed.

However, when the method disclosed in the Patent Document 3 is adopted, there is a need to stack plural sets of a high-concentration layer and a low-concentration layer successively alternately as the n-layer, thereby raising another problem of making the process complex.

In view of the aforementioned problems, an object of the present invention is to provide an LED element which achieves a high light extraction efficiency even at a low operation voltage and which can be manufactured by means of a simple process.

### Means for Solving the Problems

An LED element according to the present invention has:

a first semiconductor layer constituted of n-type nitride semiconductor;

a light emitting layer constituted of nitride semiconductor where a bottom surface thereof is in contact with a portion of an upper surface of the first semiconductor layer;

a second semiconductor layer formed on the upper layer of the light emitting layer and constituted of p-type nitride semiconductor;

a first electrode constituted of a transparent electrode where a bottom surface thereof is in contact with a portion of an upper surface of the first semiconductor layer; and

a second electrode formed on the upper layer of the second semiconductor layer,

wherein at least a region of the first semiconductor layer, which region is in contact with the first electrode, is constituted of AlₙGa₁₋ₙN (0<n≦1) and has an n-type impurity concentration larger than 1×10¹⁹/cm³.

By eager researches of the present inventors, it has been confirmed that, when the n-type first semiconductor layer is constituted of AlₙGa₁₋ₙN (0<n≦1) instead of GaN, the problem of film roughening is not raised even if the impurity concentration is set to be larger than 1×10¹⁹/cm³. As a result of this, the resistance value of the n-layer can be lowered, so that an ohmic contact between the n-layer and the transparent electrode can be achieved even when a transparent electrode is formed on the upper layer of the n-layer.

Therefore, the transparent electrode can be formed on the upper layer of the first semiconductor layer. This allows that, among the light radiated from the light emitting layer, the light propagating to the n-layer side can also be extracted via the transparent electrode, so that the light extraction efficiency can be improved.

Further, according to this construction, it is sufficient that the first semiconductor layer is simply formed of AlₙGa₁₋ₙN (0<n≦1) having an impurity concentration larger than 1×10¹⁹/cm³, and there is no need to stack plural sets of the low-concentration layer and the high-concentration layer alternately. Therefore, the LED element can be manufactured by means of a simple process without the need for a complex manufacturing process.

Here, ITO (Indium Tin Oxide), IZO (Indium Zinc Oxide), In₂O₃, SnO₂, and the like, for example, can be used as the transparent electrode.

Here, the second electrode may be constituted of a transparent electrode formed on the upper layer of the second semiconductor layer.

This allows that the transparent electrode is formed both on the n-layer side and on the p-layer side, so that the light extraction efficiency can be further enhanced.

Also, in the above construction, it may be preferable that a relationship of:

0.2≦S1/(S1+S2)≦0.3

is satisfied, assuming that an area of a contact region between the first electrode and the first semiconductor layer is S1 and that an area of a contact region between the second electrode and the second semiconductor layer is S2.

The resistance value is inversely proportional to the electrode area. For this reason, when the ratio of the first electrode which is the n-side electrode is too low, the contact resistance between the first semiconductor layer and the first electrode becomes also large even when the first semiconductor layer is achieved to be a high-concentration doped layer. Therefore, in order to reduce this contact resistance, it is preferable to set the electrode area of the first electrode to be large.

However, when the electrode area of the first electrode is set to be too large on a chip of the LED element, the region that can be occupied by the second electrode in turn decreases, so that the electrode area of the second electrode becomes small. The p-type second semiconductor layer has a larger resistance than the n-type first semiconductor layer. Therefore, decrease in the area of the second electrode will be a cause of raising the contact resistance between the second electrode and the second semiconductor layer.

Therefore, it will be understood that, in order to obtain a high optical output with an applied voltage being as low as possible, there is a preferable range with respect to the area ratio of the first electrode and the second electrode. By eager researches of the present inventors, it has been confirmed that a high effect is obtained when the area ratio is set to be within the above range.

Also, in addition to the above construction, the light emitting layer and the first electrode may be formed on the upper layer of the second semiconductor layer in a state in which the light emitting layer and the first electrode are spaced apart from each other with a gap as viewed in a horizontal direction.

This suppresses the generation of leakage current between the first electrode and the second electrode.

### Effect of the Invention

According to the present invention, there can be provided an LED element which achieves a high light extraction efficiency even at a low operation voltage and which can be manufactured by means of a simple process.

### BRIEF DESCRIPTION OF THE DRAWINGS

FIG. 1 is a schematic sectional view of an LED element according to the present invention.

FIG. 2A is a photograph of an AlGaN layer surface when the n-type impurity concentration is set to be 5×10¹⁹/cm³.

FIG. 2B is a photograph of a GaN layer surface when the n-type impurity concentration is set to be 1.5×10¹⁹/cm³.

FIG. 3A is a view of construction of an element for verification of ohmic contact (Example).

FIG. 3B is a view of construction of an element for verification of ohmic contact (Comparative Example).

FIG. 3C is a view of construction of an element for verification of ohmic contact (Reference Example).

FIG. 4A is a graph showing I-V characteristics in the Example.

FIG. 4B is a graph showing I-V characteristics in the Comparative Example.

FIG. 4C is a graph showing I-V characteristics in the Reference Example.

FIG. 5 is a graph for comparison of I-V characteristics in the Example, in the Comparative Example, and in the Conventional Example.

FIG. 6A is a view of construction of an element for verification for evaluating the light transmittance of a transparent electrode.

FIG. 6B is a view of construction of an element for verification for evaluating the light transmittance of a transparent electrode.

FIG. 6C is a graph showing the light transmittance of a transparent electrode.

FIG. 7A is a graph showing a relationship between the area ratio of the n-side electrode and the p-side electrode and the applied voltage under the same electric current.

FIG. 7B is a graph showing a relationship between the area ratio of the n-side electrode and the p-side electrode and the optical output under the same electric power.

FIG. 8 is a graph showing a relationship between the temperature of annealing ITO and the carrier concentration.

FIG. 9A is a part of a sectional view showing steps for manufacturing the LED element.

FIG. 9B is a part of a sectional view showing steps for manufacturing the LED element.

FIG. 9C is a part of a sectional view showing steps for manufacturing the LED element.

FIG. 9D is a part of a sectional view showing steps for manufacturing the LED element.

FIG. 9E is a part of a sectional view showing steps for manufacturing the LED element.

FIG. 9F is a part of a sectional view showing steps for manufacturing the LED element.

FIG. 10A is a schematic sectional view of an LED element according to another embodiment of the present invention.

FIG. 10B is a schematic sectional view of an LED element according to another embodiment of the present invention.

FIG. 11A is a sectional model view of a conventional LED element and

FIG. 11B is a sectional model view of an LED element in which a reflection electrode is provided in the construction of FIG. 11A.

### MODE FOR CARRYING OUT THE INVENTION

An LED element of the present invention will be described with reference to the drawings. Here, in each of the Figures, the dimension ratio in the Figures does not necessarily coincide with the actual dimension ratio.

### [Structure]

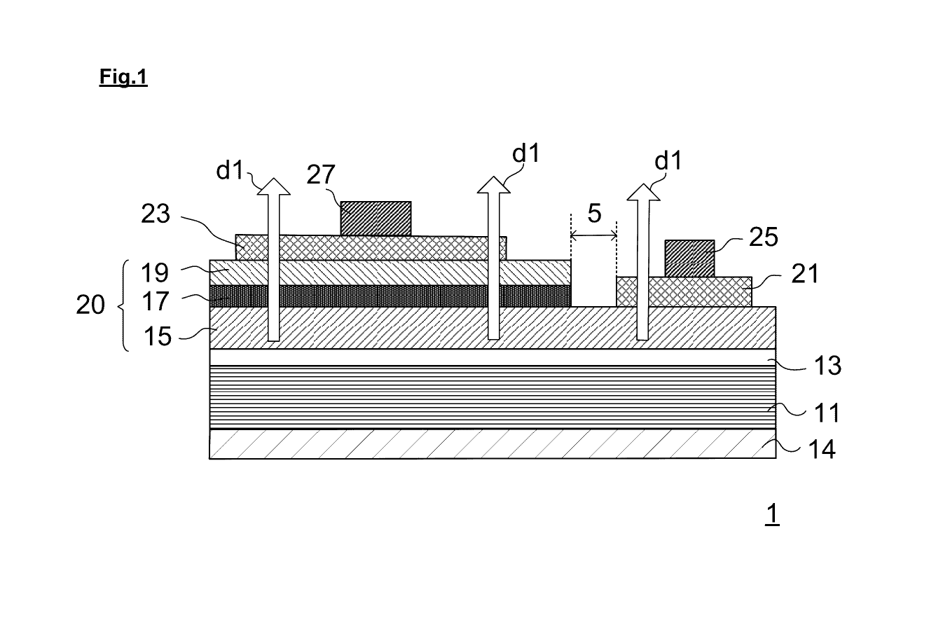

A structure of an LED element 1 according to the present invention will be described with reference to FIG. 1. FIG. 1 is a schematic sectional view of the LED element 1. Here, constituent elements identical to those shown in FIGS. 11A and 11B are denoted with identical reference symbols.

The LED element 1 includes a support substrate 11, an undoped layer 13, a reflection electrode 14, an LED layer 20, a first electrode 21, a second electrode 23, a power supply terminal 25, and a power supply terminal 27. Also, the LED layer 20 is formed in such a manner that an n-type semiconductor layer 15 (corresponding to the “first semiconductor layer”), a light emitting layer 17, and a p-type semiconductor layer 19 (corresponding to the “second semiconductor layer”) are stacked in this order from below. The first electrode 21 is formed so that a bottom surface thereof is in contact with a portion of an upper surface of the n-type semiconductor layer 15. The second electrode 23 is formed on the upper layer of the p-type semiconductor layer 19.

### (Support Substrate 11)

The support substrate 11 is constituted of a sapphire substrate. Here, instead of sapphire, the support substrate 11 may be constituted of Si, SiC, GaN, YAG, or the like.

### (Reflection Electrode 14)

The reflection electrode 14 is constituted, for example, of an Ag-based metal (alloy of Ni and Ag), Al, Rh, or the like. In the present LED element 1, it is assumed that the light radiated from the light emitting layer 17 is extracted in an upward direction (direction of an arrow symbol d1) as viewed on a paper sheet of FIG. 1, and the reflection electrode 14 functions to enhance the light emission efficiency by reflecting the light, which is radiated downward from the light emitting layer 17, in the upward direction. Here, as will be described later, unlike the conventional LED element 90 shown in FIG. 11A, the LED element 1 has a structure in which also the first electrode 21 constituting the n-side electrode is constituted of a transparent electrode, so that the light can be extracted in the d1 direction from the first electrode 21.

### (Undoped Layer 13)

The undoped layer 13 is formed of GaN. More specifically, the undoped layer 13 is formed of a low-temperature buffer layer made of GaN and an underlayer made of GaN on top thereof.

### (First Electrode 21)

The first electrode 21 included in the LED element 1 is formed, for example, of a light-transmitting electroconductive material such as ITO, IZO, In₂O₃, SnO₂, or IGZO (InGaZnOₓ), and constitutes the transparent electrode. Hereafter, the first electrode 21 will be referred to as “transparent electrode 21”.

Here, as will be described later with reference to experimental data, in the present construction, an ohmic connection is established at the interface between the n-type semiconductor layer 15 and the transparent electrode 21, thereby achieving reduction of resistance between the n-type semiconductor layer 15 and the transparent electrode 21.

### (Second Electrode 23)

In the LED element 1 according to the present embodiment, also the second electrode 23 constitutes a transparent electrode in the same manner as the first electrode 21. In other words, the second electrode 23 is formed, for example, of a light-transmitting electroconductive material such as ITO, IZO, In₂O₃, SnO₂, or IGZO (InGaZnOₓ). Hereafter, the second electrode 23 will be referred to as “transparent electrode 23”. For simplification of the process, the transparent electrode 21 and the transparent electrode 23 are preferably formed of the same material.

Here, referring to FIG. 1, the transparent electrode 21 and the transparent electrode 23 are arranged to be spaced apart from each other with a gap 5 as viewed in the horizontal direction. This produces an effect of suppressing the generation of leakage current flowing in the horizontal direction between the transparent electrode 23 and the transparent electrode 21. Here, the transparent electrode 23 is formed on the upper layer of the p-type semiconductor layer 19; the p-type semiconductor layer 19 is formed on the upper layer of the light emitting layer 17; and the light emitting layer 17 is formed on the upper layer of the n-type semiconductor layer 15 in the same manner as the transparent electrode 21. For this reason, referring to FIG. 1, the light emitting layer 17 and the transparent electrode 21 are formed on the upper layer of the n-type semiconductor layer 15 in a state in which the light emitting layer 17 and the transparent electrode 21 are spaced apart from each other with the gap 5 as viewed in the horizontal direction.

### (Power Supply Terminals 25, 27)

The power supply terminal 25 is formed on the upper layer of the transparent electrode 21, and the power supply terminal 27 is formed on the upper layer of the transparent electrode 23. The power supply terminals 25, 27 are constituted, for example, of Cr—Au. To these power supply terminals 25, 27, a wire constituted, for example, of Au, Cu, or the like (not illustrated in the drawings) is connected, and the other end of this wire is connected to a power supply pattern or the like of a substrate (not illustrated in the drawings) where the LED element 1 is placed.

### (LED Layer 20)

As described above, the LED layer 20 is formed in such a manner that the n-type semiconductor layer 15, the light emitting layer 17, and the p-type semiconductor layer 19 are stacked in this order from below.

The n-type semiconductor layer 15 has a multilayer structure that includes a layer constituted of GaN (protective layer) in a region that is in contact with the undoped layer 13 and includes a layer constituted of AlₙGa₁₋ₙN (0<n≦1) (electron supply layer) at least in a region that is in contact with the transparent electrode 21. At least the protective layer is doped with an n-type impurity such as Si, Ge, S, Se, Sn, or Te, and is preferably doped with Si.

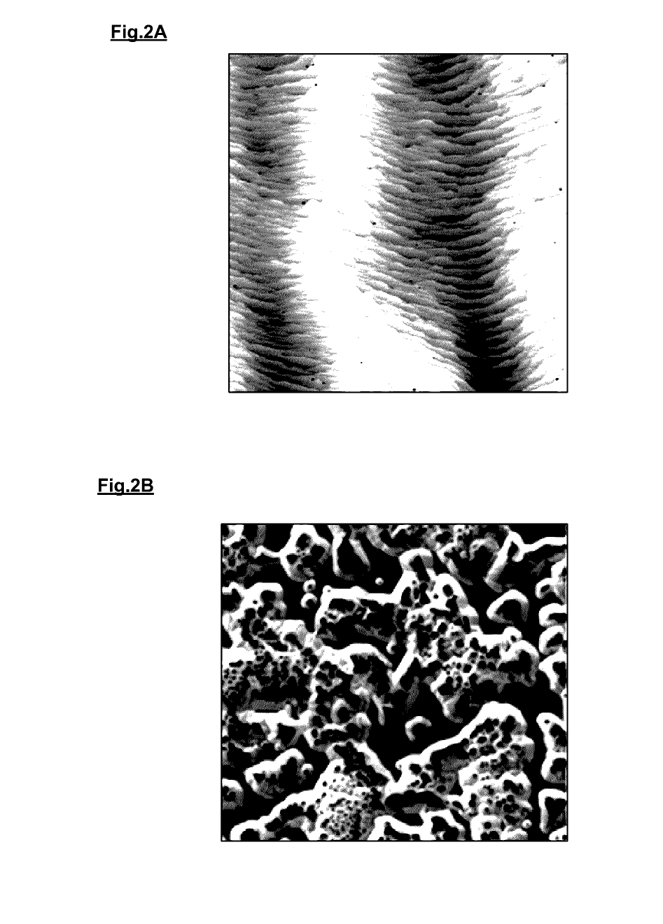

Also, the n-type semiconductor layer 15 in the region that is in contact with the transparent electrode 21 is doped with an impurity so as to have an n-type impurity concentration larger than 1×10¹⁹/cm³, preferably 3×10¹⁹/cm³. Here, as will be described later on the basis of photographs (FIG. 2A) obtained by experiments, in the present construction, film roughening does not occur in the n-type semiconductor layer 15 even if the n-type impurity concentration of the n-type semiconductor layer 15 is set to be a value larger than 1×10¹⁹/cm³ (for example, 5×10¹⁹/cm³).

The light emitting layer 17 is formed, for example, of a semiconductor layer having a multiquantum well structure in which a well layer made of InGaN and a barrier layer made of AlGaN are repeated. These layers may be undoped or may be doped to be of p-type or n-type.

The p-type semiconductor layer 19 is constituted, for example, of GaN and is doped with a p-type impurity such as Mg, Be, Zn, or C. Here, the p-type semiconductor layer 19 in the region that is in contact with the transparent electrode 23 is doped with an impurity so as to have a p-type impurity concentration larger than 3×10¹⁹/cm³, preferably 5×10¹⁹/cm³. Here, unlike the case of the n-type semiconductor doped with Si, the above-described problem of film roughening does not occur even when the doping amount is set to be larger than 1×10¹⁹/cm³ in the case of doping, for example, with Mg.

Here, the p-type semiconductor layer 19 may be constituted of AlGaN instead of GaN.

### (Others)

Although not illustrated in the drawings, an insulating layer serving as a protective film may be formed on a side surface and on an upper surface of the LED layer 20, the transparent electrode 21, and the transparent electrode 23. Here, this insulating layer serving as the protective film is preferably constituted of a material having a light-transmitting property (for example, SiO₂ or the like).

### [Verification of Presence or Absence of Film Roughening]

Next, with reference to experimental data of FIGS. 2A and 2B, description will be given on a fact that, by constructing the n-type semiconductor layer 15 with AlₙGa₁₋ₙN (0<n≦1) as in the LED element 1, film roughening is not generated even if the impurity concentration is set to be larger than 1×10¹⁹/cm³. Here, in the following, AlₙGa₁₋ₙN (0<n≦1) will be abbreviated as AlₙGa₁₋ₙN.

FIG. 2A is a photograph of an AlGaN layer surface when the n-type impurity concentration is set to be 5×10¹⁹/cm³. Also, FIG. 2B is a photograph of a GaN layer surface when the n-type impurity concentration is set to be 1.5×10¹⁹/cm³. Here, FIG. 2A shows an image captured by AFM (Atomic Force Microscopy: interatomic force microscope), and FIG. 2B shows an image captured by SEM (Scanning Electron Microscope: scanning-type electron microscope).

Referring to FIG. 2B, it will be understood that, when the n-type semiconductor layer is constituted of GaN, roughening is generated on the surface when the n-type impurity concentration is set to be 1.5×10¹⁹/cm³. Here, roughening on the surface could be confirmed in a similar manner when the impurity concentration was set to be 1.3×10¹⁹/cm³ or 2×10¹⁹/cm³. From this, it will be understood that, with respect to GaN, roughening is generated on the layer surface when the impurity concentration is set to be larger than 1×10¹⁹/cm³ as described in the Non-patent Document 1.

In contrast, from FIG. 2A, it will be understood that, when the n-type semiconductor layer is constituted of AlGaN, a step-like surface (atomic step) is confirmed and roughening is not generated on the layer surface even when the n-type impurity concentration is set to be 5×10¹⁹/cm³. Here, it has been confirmed that, in a similar manner, roughening is not generated on the layer surface even when the component ratio of Al and Ga is changed (AlₙGa₁₋ₙN) as constituent materials. Also, a photograph similar to that of FIG. 2A has been obtained when the n-type semiconductor layer is constituted of GaN and the n-type impurity concentration is set to be 0.5×10¹⁹/cm³, that is, when the n-type impurity concentration is set to be 1×10¹⁹/cm³ or less.

From the above, it will be understood that, by constructing the n-type semiconductor layer with AlₙGa₁₋ₙN, the problem of film roughening does not occur even when the n-type impurity concentration is set to be larger than 1×10¹⁹/cm³.

### [Verification of Ohmic Connection]

Next, with reference to data, description will be given on a fact that an ohmic connection is formed between the n-type semiconductor layer 15 and the transparent electrode 21 by constructing at least a region of the n-type semiconductor layer 15, which region is in contact with the transparent electrode 21, with AlₙGa₁₋ₙN having an impurity concentration larger than 1×10¹⁹/cm³.

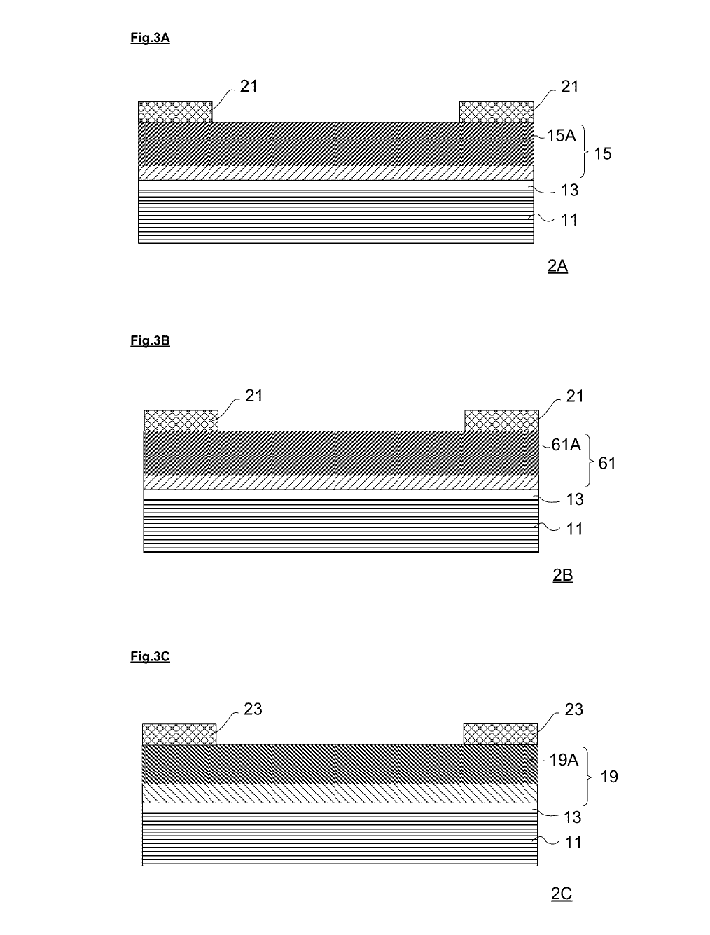

FIGS. 3A to 3C show examples of elements formed for verification of ohmic connection. Here, these elements are merely elements for verification of ohmic connection between the semiconductor layer and the transparent electrode. Therefore, unlike the LED element 1, the elements were constructed within a range needed for verification. Also, in FIGS. 3A to 3C, ITO was adopted as the transparent electrodes 21 and 23.

### EXAMPLE

In the same manner as the LED element 1, the element 2A for verification shown in FIG. 3A is constructed in such a manner that the n-type semiconductor layer 15 is formed via the undoped layer 13 on the support substrate 11, and the transparent electrode 21 is formed at two sites on top thereof. The n-type semiconductor layer 15 has, at the topmost position including the region that is in contact with the transparent electrode 21, a high-concentration layer 15A constituted of AlₙGa₁₋ₙN having an impurity concentration of 3×10¹⁹/cm³.

### Comparative Example

The element 2B for verification shown in FIG. 3B is an element in which an n-type semiconductor layer 61 constituted of GaN is formed in place of the n-type semiconductor layer 15 constituted of AlₙGa₁₋ₙN in the element 2A for verification. This n-type semiconductor layer 61 has, at the topmost position including the region that is in contact with the transparent electrode 21, a layer 61A constituted of GaN having an impurity concentration of 1×10¹⁹/cm³ (upper limit value at which the film roughening is not generated).

### Reference Example

The element 2C for verification shown in FIG. 3C is an element for verifying ohmic connection at the interface between the transparent electrode 23 constituting the p-side electrode and the p-type semiconductor layer 19. Specifically, the p-type semiconductor layer 19 is formed via the undoped layer 13 on the support substrate 11, and the transparent electrode 23 is formed at two sites on top thereof. The p-type semiconductor layer 19 has, at the topmost position including the region that is in contact with the transparent electrode 23, a high-concentration layer 19A constituted of GaN having an impurity concentration of 8×10¹⁹/cm³.

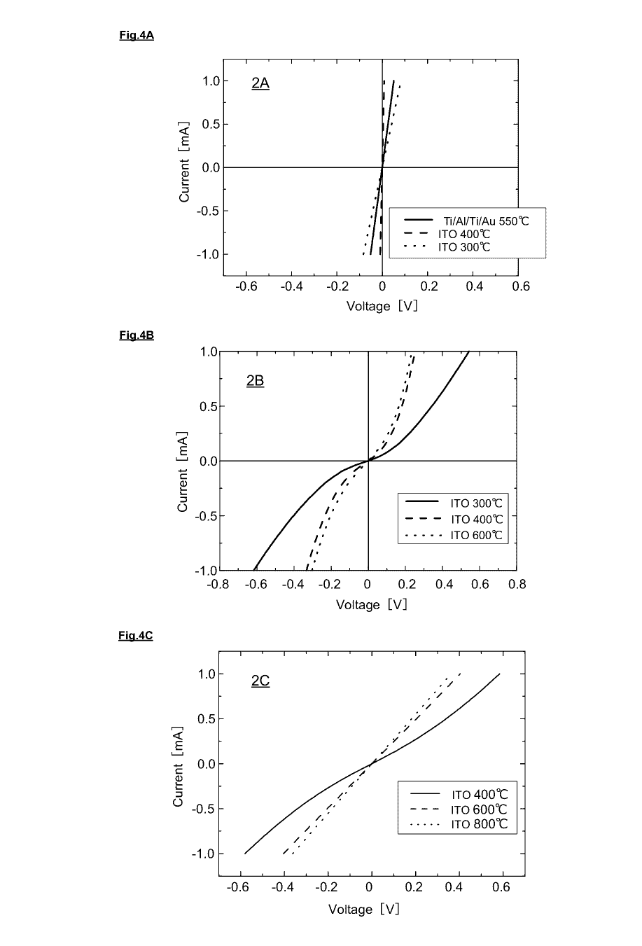

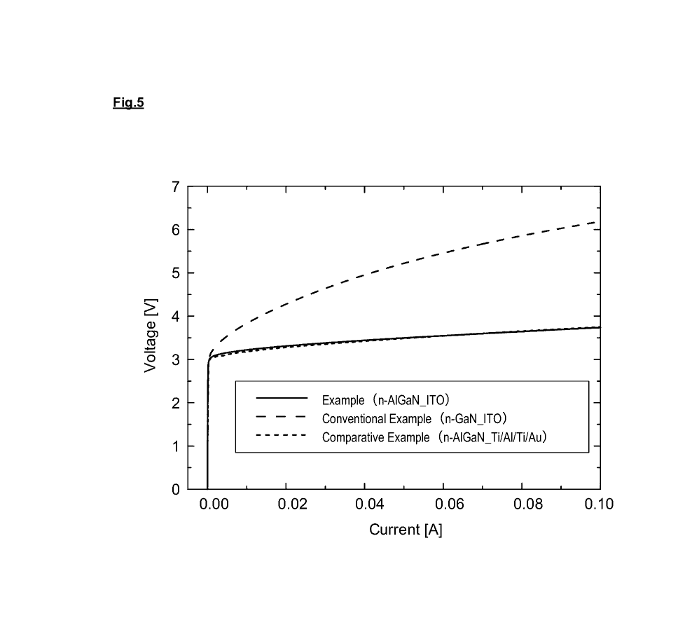

FIGS. 4A and 4B show graphs obtained by measurement of I-V characteristics for the respective elements 2A, 2B for verification between the n-type semiconductor layer and the transparent electrode 21 stacked on top thereof. Specifically, a voltage V is applied between the two transparent electrodes 21 that are formed to be spaced apart from each other, and the relationship between the value of this V and the amount of electric current I that flows via the n-type semiconductor layer (15, 61) is made into a graph. In further detail, this graph is obtained in such a manner that, by gradually changing the voltage applied between the two from 0 to a negative voltage or from 0 to a positive voltage with 0 V serving as a standard, the electric current I is measured for each applied voltage, and the relationship between the applied voltage and the electric current is made into a graph.

Also, FIG. 4C shows a graph obtained by measurement of I-V characteristics for the element 2C for verification between the p-type semiconductor layer 19 and the transparent electrode 23 stacked on top thereof. The method of measurement is the same as that of the elements 2A, 2B for verification.

FIG. 4A corresponds to the element 2A for verification (Example); FIG. 4B corresponds to the element 2B for verification (Comparative Example); and FIG. 4C corresponds to the element 2C for verification (Reference Example). Here, FIG. 4A also illustrates the I-V characteristics when an ordinary metal electrode material (Ti/Al/Ti/Au) is formed in place of the transparent electrode 21 for comparison for confirming formation of ohmic connection.

According to FIG. 4A, it will be understood that, when a region of the n-type semiconductor layer 15 which region is in contact with the transparent electrode 21 is constituted of AlₙGa₁₋ₙN having an impurity concentration of 3×10¹⁹/cm³, approximately linear I-V characteristics are exhibited even when the transparent electrode 21 made of ITO is formed on top thereof, in the same manner as in the case in which the metal electrode (Ti/Al/Ti/Au) is formed. Also, in both of the cases in which the temperature for annealing ITO is 300° C. and 400° C., little change is seen in the characteristics thereof. In other words, it will be understood that, when the n-type semiconductor layer 15 of the region that is in contact with the transparent electrode 21 is constituted of AlₙGa₁₋ₙN having an impurity concentration of 3×10¹⁹/cm³, an ohmic connection similar to that of the case in which a metal electrode is formed on top thereof is achieved.

In contrast, referring to FIG. 4B, in the case in which the n-type semiconductor layer 61 of the region that is in contact with the transparent electrode 21 is constituted of GaN having an impurity concentration of 1×10¹⁹/cm³, the gradient of the I-V characteristic curve in a region in a neighborhood of 0 V is milder than the gradient of the I-V characteristic curve in a negative voltage region and in a positive voltage region distant from 0 V. This shows that, while an electric current is more liable to flow when a voltage having a larger absolute value is applied, the electric current is less liable to flow when a voltage having a smaller absolute value close to 0 V is applied, thereby suggesting that a Schottky connection is formed.

By raising the temperature of annealing ITO, the carrier concentration of ITO can be increased. However, according to FIG. 4B, it will be understood that, even when the temperature of annealing ITO is raised to 600° C., a Schottky connection is still formed, and an ohmic connection is not achieved. In other words, it can be concluded that, when a region of the n-type semiconductor layer 15 which region is in contact with the transparent electrode 21 is constituted of GaN having an impurity concentration of 1×10¹⁹/cm³, an ohmic connection cannot be achieved between the n-type semiconductor layer 15 and the transparent electrode 21.

Also, according to FIG. 4C, it will be understood that, when a region of the p-type semiconductor layer 19 which region is in contact with the transparent electrode 23 is constituted of GaN having an impurity concentration of 8×10¹⁹/cm³, approximately linear I-V characteristics are exhibited when the annealing temperature is 600° C. or 800° C., thereby showing that an ohmic connection is achieved. Here, when the annealing temperature is 400° C., the gradient of the I-V characteristic curve in a region in a neighborhood of 0 V is a little milder than the gradient of the I-V characteristic curve in a negative voltage region and in a positive voltage region distant from 0 V, thereby showing that a little distortion is generated in the ohmic property.

In other words, according to FIG. 4C, it will be understood that, when a region of the p-type semiconductor layer 19 which region is in contact with the transparent electrode 23 is constituted of GaN having an impurity concentration of 8×10¹⁹/cm³, an ohmic connection is achieved as well. Here, in the case of the p-type semiconductor layer 19, the material for doping is a p-type impurity such as Mg instead of Si, unlike the case of the n-type semiconductor layer 15. Therefore, as described before, even when the p-type semiconductor layer 19 is doped so as to achieve an impurity concentration of about 8×10¹⁹/cm³, the problem of film roughening does not occur.

FIG. 5 is a graph for comparison of I-V characteristics in the Example, in the Comparative Example, and in the Conventional Example. The Example pertains to the construction of the LED element 1 shown in FIG. 1, while the Conventional Example pertains to the construction of the LED element 90 shown in FIG. 11B and, in each of the cases, the relationship between the voltage and the electric current flowing between the power supply terminals 25 and 27 is made into a graph. Also, the Comparative Example pertains to a construction of using the transparent electrode 21 in place of the metal electrode 63 in the construction of the LED element 90 shown in FIG. 11B, and the relationship between the voltage and the electric current is made into a graph in the same manner.

According to FIG. 5, it will be understood that the LED element 1 corresponding to the Example achieves I-V characteristics equivalent to those of the Conventional Example using a metal electrode, and a sufficient electric current can be let to flow at a low voltage. In contrast, it will be understood that, in the Comparative Example, a high voltage must be applied in order to let an equivalent electric current flow, leading to decrease in the light-emission efficiency.

In view of the above, it will be understood that, in the case in which a constituent material of the n-type semiconductor layer 15 is GaN, an ohmic connection is not achieved between the n-type semiconductor layer 15 and the transparent electrode 21 even when the impurity concentration is set to be 1×10¹⁹/cm³ which is the maximum impurity concentration in the range in which the problem of film roughening does not occur. In this case, the resistance value between the transparent electrode 21 and the n-type semiconductor layer 15 becomes large, and a voltage needed for an electric current, which is needed for light emission, to flow becomes high.

By using AlₙGa₁₋ₙN as the n-type semiconductor layer 15 as in the LED element 1, a high-concentration layer 15A exceeding 1×10¹⁹/cm³ can be achieved without generating the film roughening. Further, by bringing such a high-concentration layer 15A into contact with the transparent electrode 21, an ohmic connection between the n-type semiconductor layer 15 and the transparent electrode 21 is achieved. Therefore, even when the transparent electrode 21 serving as the n-side electrode is formed on an upper surface of the n-type semiconductor layer 15, a sufficient electric current can be let to flow through the light emitting layer at a low voltage applied. Further, because the electrode 21 is formed to be transparent, the light propagating toward this transparent electrode 21 side can be extracted to the outside, thereby improving the light extraction efficiency.

Furthermore, by forming the transparent electrode 23 serving as the p-side electrode as in the LED element 1, the light propagating toward this transparent electrode 23 also can be extracted to the outside, thereby greatly improving the light extraction efficiency. Here, an ohmic connection at the interface between the transparent electrode 23 and the p-side semiconductor layer 19 is also achieved, so that, even when the transparent electrode 23 is formed on an upper surface of the p-side semiconductor layer 19, a sufficient electric current can be let to flow through the light emitting layer at a low voltage applied.

### [Verification of Light Transmittance]

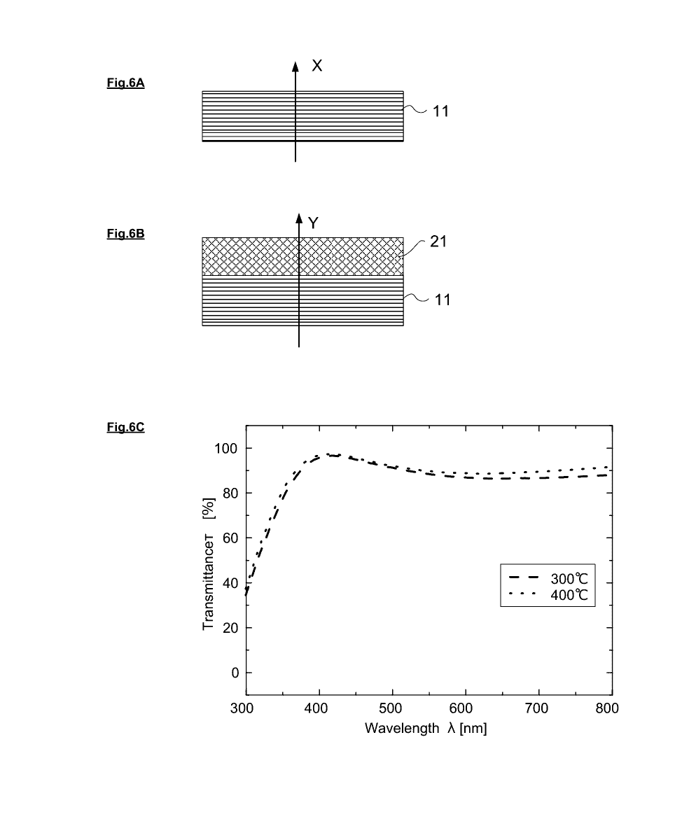

Next, the light transmittance of the transparent electrode 21 will be verified. FIGS. 6A and 6B are conceptual views for describing a method of verification, and FIG. 6C is a graph showing a result of verification. Here, a similar description can be given on the transparent electrode 23 as well.

Referring to FIG. 6A, light is radiated from the back surface of the support substrate 11 made of sapphire, and the light quantity X at the front surface is measured. Similarly, referring to FIG. 6B, in an element in which the transparent electrode 21 is formed on the support substrate 11, light is radiated from the back surface of the support substrate 11, and the light quantity Y at the front surface (transparent electrode 21 side) is measured. Such measurements are carried out while changing the wavelength of light, and the transmittance τ=Y/X is calculated for each wavelength and made into a graph, which is shown in FIG. 6C. Here, the measurement of light quantity was carried out using an ultraviolet-visible spectrophotometer.

According to FIG. 6C, it will be understood that, in a range of λ≧400 nm, a transmittance τ of 90% or more is achieved irrespective of whether the temperature of annealing ITO is 300° C. or 400° C. Also, in a range of λ≧350 nm, a transmittance τ of 80% or more is achieved. Therefore, it will be understood that the transparent electrode 38 has a sufficient function of transmitting light. In other words, when the transparent electrode 21 is formed on an upper surface of the n-type semiconductor layer 15 as shown in FIG. 1, the light propagating toward this transparent electrode 21 side is not greatly damped in the transparent electrode 21, and the light can be extracted to the outside at a high efficiency.

### [Verification of Area Ratio]

Next, a preferable area ratio of the transparent electrode 21 which is the n-side electrode and the transparent electrode 23 which is the p-side electrode will be described.

The resistance value is inversely proportional to the electrode area. For this reason, when the ratio of the transparent electrode 21 which is the n-side electrode is too low, the contact resistance between the n-type semiconductor layer 15 and the transparent electrode 21 becomes also large even when the interface between the n-type semiconductor layer 15 and the transparent electrode 21 is achieved to be a high-concentration doped layer. Therefore, in order to reduce this contact resistance, it is preferable to set the electrode area of the transparent electrode 21 to be large.

However, when the electrode area of the transparent electrode 21 is set to be too large on a chip of the LED element, the region that can be occupied by the transparent electrode 23 which is the p-side electrode in turn decreases, so that the electrode area of the transparent electrode 23 becomes small. The p-type semiconductor layer 19 has a larger contact resistance than the n-type semiconductor layer 15. Therefore, decrease in the area of the transparent electrode 23 will be a cause of raising the resistance between the p-type semiconductor layer 19 and the transparent electrode 23.

Therefore, it can be said that, in order to ensure a sufficient electric current with an applied voltage being as low as possible, there is a preferable range with respect to the area ratio of the transparent electrode 21 on the n-side and the transparent electrode 23 on the p-side.

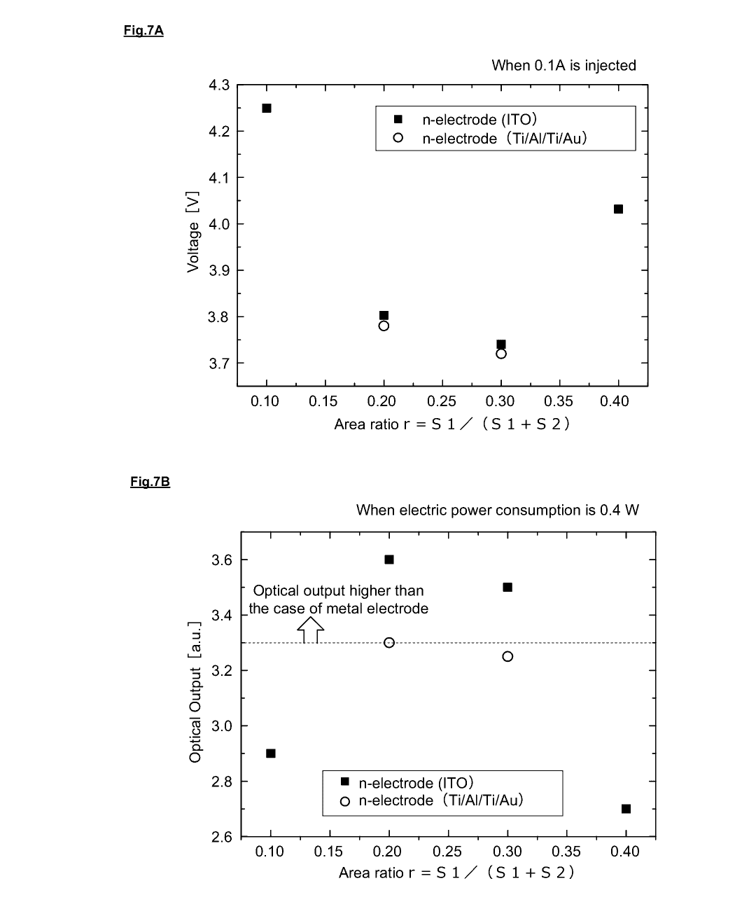

FIG. 7A is a graph showing a relationship between the area ratio of the transparent electrode 21 (n-side electrode) and the transparent electrode 23 (p-side electrode) and the applied voltage under the same electric current. Hereinafter, the electrode area of the n-side electrode will be denoted with S1, and the electrode area of the p-side electrode will be denoted with S2. At this time, in FIG. 7A, the lateral axis is defined to represent the area ratio r=S1/(S1+S2). Here, FIG. 7A also shows data of the conventional LED element 90 in which the n-side electrode is made of a metal electrode 63 (Ti/Al/Ti/Au) with respect to the cases of r=0.2 and r=0.3 for comparison. Also, in FIG. 7A, the applied voltage is adjusted so that an electric current of 0.1 A is allowed to flow between the two power supply terminals 25 and 27.

According to FIG. 7A, it will be understood that, in the LED element 1 in which the n-side electrode is made of the transparent electrode 21, the voltage needed for an electric current of 0.1 A to flow is high when the area ratio r is too small or too large. This result conforms to the above-described consideration.

Further, it will be understood that, in the range in which the area ratio r is 0.2 or more and 0.3 or less, an electric current of 0.1 A can be let to flow with an applied voltage equivalent to that of the conventional LED element 90 in which the n-side electrode is made of the metal electrode 63.

FIG. 7B is a graph showing a relationship between the area ratio of the n-side electrode and the p-side electrode and the optical output under the same electric power. In the same manner as in FIG. 7A, the lateral axis is defined to represent the area ratio r. Also, the longitudinal axis is defined to represent the optical output. The applied electric current and the applied voltage are adjusted so as to attain an electric power consumption of 0.4 W. Also, in the same manner as in FIG. 7A, FIG. 7B also shows data of the conventional LED element 90 in which the n-side electrode is made of the metal electrode 63 with respect to the cases of r=0.2 and r=0.3 for comparison.

According to FIG. 7B, it will be understood that, in the LED element 1 in which the n-side electrode is made of the transparent electrode 21, the optical output is low when the area ratio r is too small or too large in a state in which the electric power consumption is made to be constant. In light of FIG. 7A, this suggests that, within such a range of the area ratio r, a sufficient electric current cannot be let to flow between the two power supply terminals 25 and 27, and a high optical output cannot be obtained.

In contrast, it will be understood that, within a range in which the area ratio r is 0.2 or more and 0.3 or less, a higher optical output is obtained than in the case of the conventional LED element 90 in which the n-side electrode is made of the metal electrode 63, under the same electric power consumption.

From the above, it will be understood that, in the LED element 1, the effect of obtaining a sufficient optical output under a low applied voltage is further enhanced particularly by setting the area ratio r to be 0.2 or more and 0.3 or less.

### [Temperature of Annealing ITO]

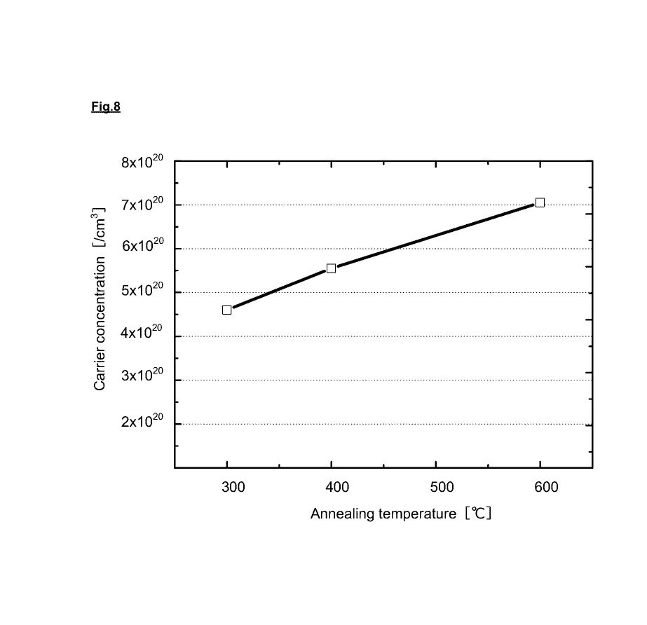

FIG. 8 is a graph showing a relationship between the temperature of annealing ITO and the carrier concentration in ITO.

Even if the impurity concentration of the n-type semiconductor layer 15 is set to be sufficiently high, the resistance value between the n-type semiconductor layer 15 and the transparent electrode 21 cannot be lowered when the carrier concentration of the material constituting the transparent electrode 21 is considerably low. According to FIG. 8, it will be understood that, in the case in which ITO is used as the transparent electrode 21, a carrier concentration of 4.5×10²⁰/cm³ in ITO is achieved when the temperature of annealing ITO is 300° C. When such a sufficiently high ITO carrier concentration is achieved, the resistance value between the n-type semiconductor layer 15 and the transparent electrode (ITO) 21 is dependent on the impurity concentration of the n-type semiconductor layer 15 rather than on the carrier concentration of ITO.

According to FIG. 8, it will be understood that, when the transparent electrode 21 is made of ITO, a sufficient carrier concentration is ensured in ITO. This constitutes another ground showing that an ohmic connection is achieved between the n-type semiconductor layer 15 and the transparent electrode 21, as shown in FIGS. 4A, 4B, and 5.

### [Method for Manufacturing LED Element 1]

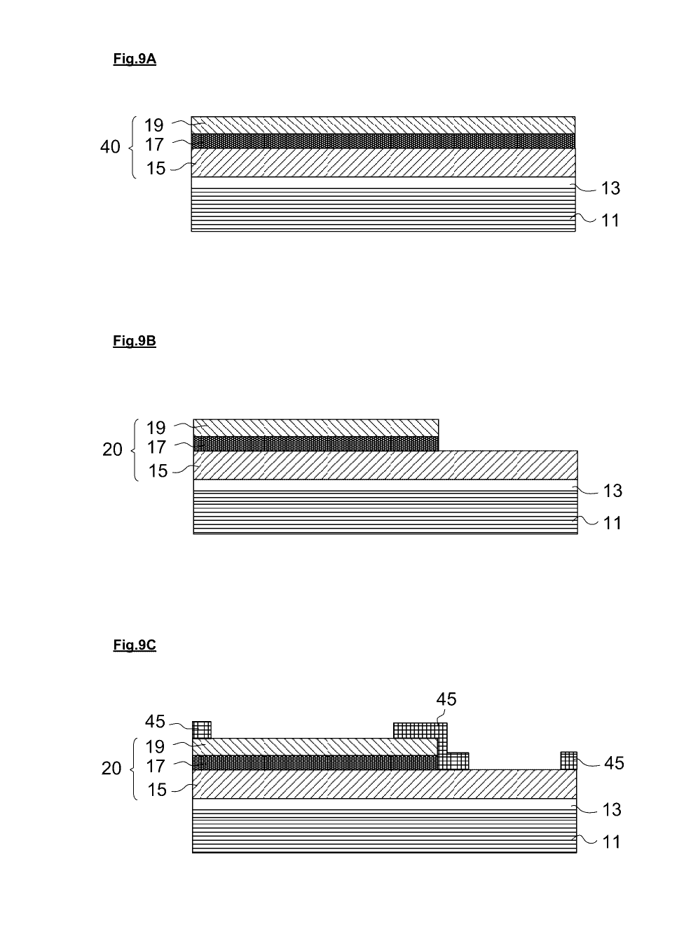

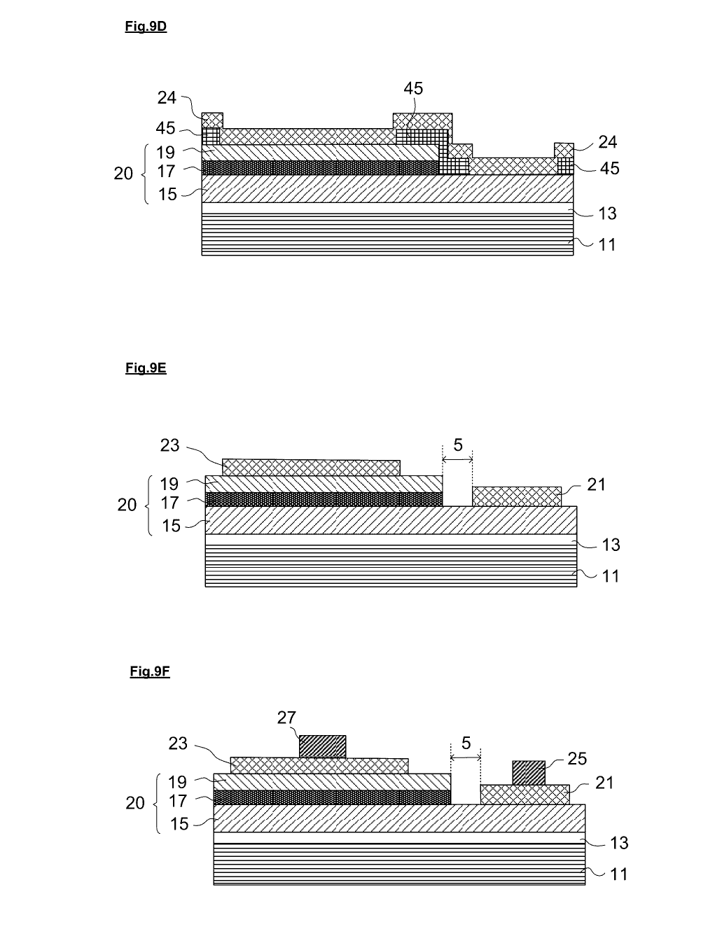

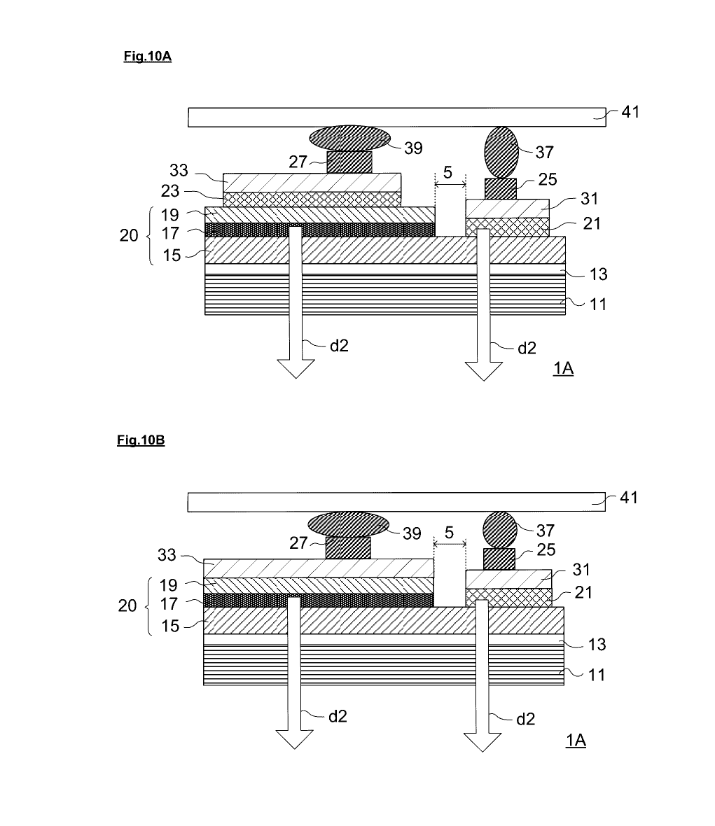

Next, one example of a method for manufacturing the LED element 1 of the present invention will be described with reference to the sectional views of FIGS. 9A to 9F showing steps for manufacturing the LED element 1 and FIG. 1. Here, the production conditions and the dimensions such as the film thickness in the following description of the manufacturing method are merely examples, so that the present invention is not limited to these numerical values.

### (Step S1)

Referring to FIG. 9A, an undoped layer 13 and an LED epi-layer 40 are formed on a support substrate 11. This is carried out, for example, through the following steps.

### <Preparation of Support Substrate 11>

First, when a sapphire substrate is to be used as the support substrate 11, cleaning of a c-plane sapphire substrate is carried out. More specifically, this cleaning is carried out, for example, by placing the c-plane sapphire substrate in a processing furnace of an MOCVD (Metal Organic Chemical Vapor Deposition: organic metal chemical gas-phase vapor deposition) apparatus and raising the temperature within the furnace to be, for example, 1150° C. while allowing a hydrogen gas to flow at a flow rate of 10 slm in the processing furnace.

### <Forming Undoped Layer 13>

Next, a low-temperature buffer layer made of GaN is formed on the surface of the support substrate 11 (c-plane sapphire substrate), and further an underlayer made of GaN is formed on top thereof. The low-temperature buffer layer and the underlayer correspond to the undoped layer 13.

A more specific method of forming the undoped layer 13 is, for example, as follows. First, the pressure within the furnace of the MOCVD apparatus is set to be 100 kPa, and the temperature within the furnace is set to be 480° C. Then, trimethylgallium having a flow rate of 50 μmol/min and ammonia having a flow rate of 250000 μmol/min are supplied as source material gases for 68 seconds into the processing furnace while allowing a nitrogen gas and a hydrogen gas each having a flow rate of 5 slm to flow as carrier gases in the processing furnace. By this process, the low-temperature buffer layer made of GaN and having a thickness of 20 nm is formed on the surface of the support substrate 11.

Next, the temperature within the furnace of the MOCVD apparatus is raised to 1150° C. Then, trimethylgallium having a flow rate of 100 μmol/min and ammonia having a flow rate of 250000 μmol/min are supplied as source material gases for 30 minutes into the processing furnace while allowing a nitrogen gas having a flow rate of 20 slm and a hydrogen gas having a flow rate of 15 slm to flow as carrier gases in the processing furnace. By this process, the underlayer made of GaN and having a thickness of 1.7 μm is formed on the surface of the first buffer layer.

<Forming n-type Semiconductor Layer 15>

Next, an electron supply layer having a composition of AlₙGa₁₋ₙN (0<n≦1) is formed on top of the undoped layer 13. This electron supply layer corresponds to the n-type semiconductor layer 15.

A more specific method of forming the n-type semiconductor layer 15 is, for example, as follows. First, the pressure within the furnace of the MOCVD apparatus is set to be 30 kPa. Then, trimethylgallium having a flow rate of 94 μmol/min, trimethylaluminum having a flow rate of 6 μmol/min, ammonia having a flow rate of 250000 μmol/min, and tetraethylsilane having a flow rate of 0.025 μmol/min are supplied as source material gases for 30 minutes into the processing furnace while allowing a nitrogen gas having a flow rate of 20 slm and a hydrogen gas having a flow rate of 15 slm to flow as carrier gases in the processing furnace. By this process, a high-concentration electron supply layer having a composition of Al_{0.06}Ga_{0.94}N with an Si concentration of 3×10¹⁹/cm and a thickness of 1.7 μm is formed on top of the undoped layer 13. In other words, by this step, the n-type semiconductor layer 15 having the high-concentration electron supply layer with an Si concentration of 3×10¹⁹/cm³ and a thickness of 1.7 μm is formed at least with respect to the region of the upper surface.

Here, silicon (Si), germanium (Ge), sulfur (S), selenium (Se), tin (Sn), tellurium (Te), and others may be used as the n-type impurity contained in the n-type semiconductor layer 15. Among these, silicon (Si) is especially preferable.

### <Forming Light Emitting Layer 17>

Next, a light emitting layer 17 having a multiquantum well structure in which a well layer constituted of GaInN and a barrier layer constituted of n-type AlGaN are periodically repeated is formed on top of the n-type semiconductor layer 15.

A more specific method of forming the light emitting layer 17 is, for example, as follows. First, the pressure within the furnace of the MOCVD apparatus is set to be 100 kPa, and the temperature within the furnace is set to be 830° C. Then, a step of supplying trimethylgallium having a flow rate of 10 μmol/min, trimethylindium having a flow rate of 12 μmol/min, and ammonia having a flow rate of 300000 μmol/min as source material gases for 48 seconds into the processing furnace is carried out while allowing a nitrogen gas having a flow rate of 15 slm and a hydrogen gas having a flow rate of 1 slm to flow as carrier gases in the processing furnace. Thereafter, a step of supplying trimethylgallium having a flow rate of 10 μmol/min, trimethylaluminum having a flow rate of 1.6 μmol/min, tetraethylsilane having a flow rate of 0.002 μmol/min, and ammonia having a flow rate of 300000 μmol/min for 120 seconds into the processing furnace is carried out. Thereafter, by repeating these two steps, the light emitting layer 17 having a multiquantum well structure of 15 periods by the well layer made of GaInN having a thickness of 2 nm and the barrier layer made of n-type AlGaN having a thickness of 7 nm is formed on an upper surface of the n-type semiconductor layer 15.

<Forming p-type Semiconductor Layer 19>

Next, a hole supply layer having a composition of GaN is formed on top of the light emitting layer 17. This hole supply layer corresponds to the p-type semiconductor layer 19.

A more specific method of forming the p-type semiconductor layer 19 is, for example, as follows. First, the pressure within the furnace of the MOCVD apparatus is maintained to be 100 kPa, and the temperature within the furnace is raised to 1050° C. while allowing a nitrogen gas having a flow rate of 15 slm and a hydrogen gas having a flow rate of 25 slm to flow as carrier gases in the processing furnace. Thereafter, trimethylgallium having a flow rate of 35 μmol/min, ammonia having a flow rate of 250000 μmol/min, and biscyclopentadienyl having a flow rate of 0.1 μmol/min are supplied as source material gases for 360 seconds into the processing furnace. By this process, a hole supply layer having a composition of GaN and having a thickness of 120 nm is formed on the surface of the light emitting layer 17.

Further thereafter, by changing the flow rate of biscyclopentadienyl to 0.2 μmol/min and supplying the source material gases for 20 seconds, a high-concentration layer (contact layer) made of p-type GaN and having a thickness of 5 nm is formed.

Here, magnesium (Mg), beryllium (Be), zinc (Zn), carbon (C), and others may be used as the p-type impurity.

In this manner, the LED epi-layer 40 made of the undoped layer 13, the n-type semiconductor layer 15, the light emitting layer 17, and the p-type semiconductor layer 19 is formed on the support substrate 11.

### (Step S2)

Next, an activation process is carried out on the wafer obtained in the step S1. More specifically, an activation process of 15 minutes at 650° C. in a nitrogen atmosphere is carried out using an RTA (Rapid Thermal Anneal: rapid heating) apparatus.

### (Step S3)

Referring to FIG. 9B, the p-type semiconductor layer 19 and the light emitting layer 17 are removed by dry etching using an ICP apparatus until a part of an upper surface of the n-type semiconductor layer 15 is exposed. Here, in the present step S3, a part of the n-type semiconductor layer 15 may be removed by etching as well. The high-concentration n-type semiconductor layer 15 having an Si concentration of 3×10¹⁹/cm³ is exposed by the present step S3.

The LED layer 20 is formed by the present step S3.

### (Step S4)

Referring to FIG. 9C, a resist 45 is formed on a part of the upper surface of the p-type semiconductor layer 19 and on a part of the upper surface of the exposed n-type semiconductor layer 15. At the time point at which the present step S4 is finished, the p-type semiconductor layer 19 and the n-type semiconductor layer 15 are still exposed with respect to regions where the resist 45 is not formed.

The resist 45 is formed at a site where the electroconductive light-transmitting material film formed in the next step S5 is to be removed by lift-off in the step S6 subsequent thereto. In other words, the transparent electrode 21 and the transparent electrode 23 are formed by remaining of the electroconductive light-transmitting material film formed in the regions where the resist 45 is not formed in the next step S5.

### (Step S5)

Referring to FIG. 9D, an electroconductive light-transmitting material film 24 such as ITO or IZO is formed to a thickness of 30 nm to 600 nm by the sputtering method so as to extend over the whole surface including the resist 45, the exposed upper surface of the p-type semiconductor layer 19, and the exposed upper surface of the n-type semiconductor layer 15.

### (Step S6)

By lift-off of the resist using a chemical agent such as acetone, the resist 45 and the electroconductive light-transmitting material film 24 located immediately thereabove are removed. Referring to FIG. 9E, the electroconductive light-transmitting material film 24 is separated into two by this process, whereby the transparent electrode 21 and the transparent electrode 23 are formed. During this, a gap 5 with respect to the horizontal direction is formed between the transparent electrode 21 and the transparent electrode 23. Thereafter, in order to prompt recrystallization of the formed light-transmitting material constituting the transparent electrodes 21, 23, an activation process (contact annealing) is carried out at 600° C. for 5 minutes in a nitrogen atmosphere using an RTA apparatus.

### (Step S7)

Referring to FIG. 9F, a power supply terminal 25 is formed on an upper surface of the transparent electrode 21, and a power supply terminal 27 is formed on an upper surface of the transparent electrode 23. More specifically, an electroconductive material film for forming the power supply terminals 25, 27 (for example, a material film made of Cr having a thickness of 100 nm and Au having a thickness of 3 μm) is formed over the whole surface, and thereafter the power supply terminals 25, 27 are formed by lift-off. Subsequently, sintering is carried out at 250° C. for one minute in a nitrogen atmosphere.

### (Step S8)

Next, by using an electron beam vapor deposition apparatus (EB apparatus), a reflection electrode 14 made of Al or Ag is vapor-deposited to a thickness of, for example, about 120 nm on the back surface of the support substrate 11 (See FIG. 1). In carrying out the step S8, the reflection electrode 14 may be vapor-deposited from above after the whole substrate is turned upside down, or alternatively, the reflection electrode 14 may be vapor-deposited directly from the back surface side.

As subsequent steps, the exposed side surface of the element and the upper surface of the element other than the power supply terminals 25, 27 are covered with an insulating layer having a high light transmittance. More specifically, an SiO₂ film is formed by the EB apparatus. Here, an SiN film may be formed instead. Then, the elements are separated from each other, for example, by a laser dicing apparatus, and wire bonding is carried out on the power supply terminals 25 and 27.

### [Other Embodiments]

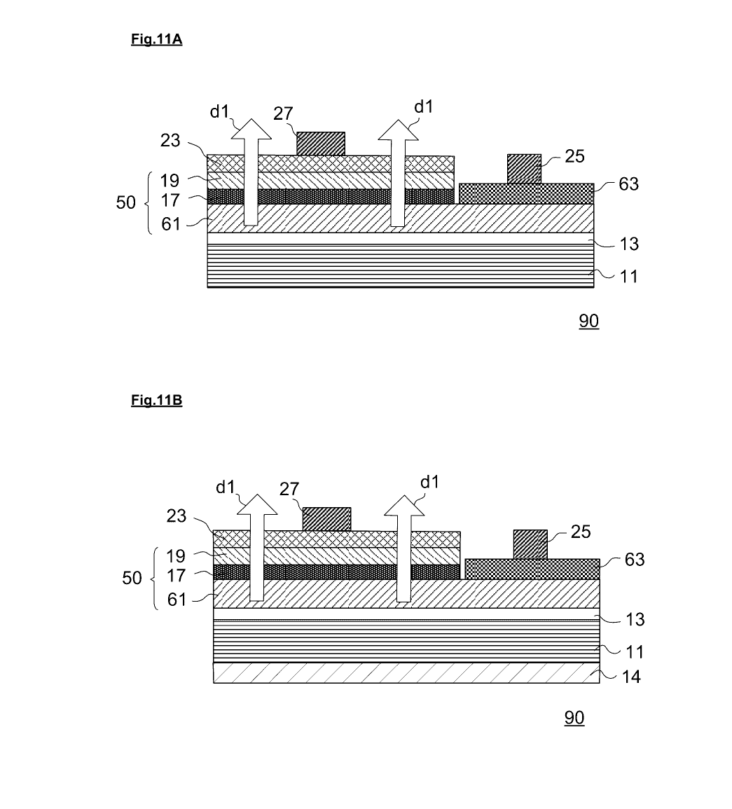

Hereafter, other embodiments will be described.

<1> The LED element 1 shown in FIG. 1 has a construction in which the light is extracted in an upward direction (to the transparent electrodes 21, 23 side) of the paper sheet. In contrast, a construction may be adopted in which the light is extracted in a downward direction (in the direction of the arrow symbol d2) of the paper sheet, as in the LED element 1A shown in FIG. 10A.

The LED element 1A shown in FIG. 10A includes a support substrate 11, an undoped layer 13, an LED layer 20, a transparent electrode 21, a transparent electrode 23, a power supply terminal 25, and a power supply terminal 27 in the same manner as in the LED element 1 shown in FIG. 1. Further, the LED layer 20 is constituted of an n-type semiconductor layer 15, a light emitting layer 17, and a p-type semiconductor layer 19. A region of the n-type semiconductor layer 15, which region is in contact with the transparent electrode 21, is constituted of AlₙGa₁₋ₙN (0<n≦1) doped with an impurity so as to attain an n-type impurity concentration being larger than 1×10¹⁹/cm³, preferably being 3×10¹⁹/cm³ or more.

Further, the power supply terminal 25 is formed via a reflection electrode 31 on top of the transparent electrode 21. Similarly, the power supply terminal 27 is formed via a reflection electrode 33 on top of the transparent electrode 23. Further, the power supply terminal 25 is electrically connected to a substrate 41 via a bonding metal 37, and the power supply terminal 27 is electrically connected to the substrate 41 via a bonding metal 39.

According to this construction, the light propagating upward among the light radiated from the light emitting layer 17 is radiated onto the reflection electrode 33 via the transparent electrode 23 and is reflected at the reflection electrode 33 to be emitted toward the support substrate 11 side. Here, by receiving an influence of the difference in the refractive index between air and the support substrate 11 achieved by sapphire or the like, part of the light is not radiated to the outside from the support substrate 11 but is reflected at the interface thereof, so as to repeat multiple reflection within the LED element 1A. At this time, that part of the light propagates toward the transparent electrode 21 side. Here, because the light transmitted through the transparent electrode 21 is radiated onto the reflection electrode 31, the light is reflected at this reflection electrode 31 to be guided again to the support substrate 11 side.

In other words, when a metal electrode 63 is used as the n-side electrode, as in the conventional case, in place of the transparent electrode 21, a part of the light propagating toward the n-side electrode among the light reflected at the interface between air and the support substrate 11 is absorbed by the metal electrode 63 constituting the n-side electrode. Therefore, in the present LED element 1A as well, the light extraction efficiency can be improved by adopting the transparent electrode 21 as the n-side electrode.

Here, in the case of the LED element 1A, the light propagating upward can be reflected downward by the reflection electrode 33, so that the transparent electrode 23 need not be necessarily formed (See FIG. 10B).

<2> In the LED elements 1 and 1A, the p-type semiconductor layer 19 may be constituted of AlGaN. In this case, the p-type semiconductor layer 19 can be formed, for example, by the following method.

First, the pressure within the furnace of the MOCVD apparatus is maintained to be 100 kPa, and the temperature within the furnace is raised to 1050° C. while allowing a nitrogen gas having a flow rate of 15 slm and a hydrogen gas having a flow rate of 25 slm to flow as carrier gases in the processing furnace. Thereafter, trimethylgallium having a flow rate of 35 μmol/min, trimethylaluminum having a flow rate of 20 μmol/min, ammonia having a flow rate of 250000 μmol/min, and biscyclopentadienyl having a flow rate of 0.1 μmol/min are supplied as source material gases for 60 seconds into the processing furnace. By this process, a hole supply layer having a composition of Al_{0.3}Ga_{0.7}N and having a thickness of 20 nm is formed on the surface of the light emitting layer 33. Thereafter, by changing the flow rate of trimethylaluminum to 9 μmol/min and supplying the source material gases for 360 seconds, a hole supply layer having a composition of Al_{0.13}Ga_{0.87}N and having a thickness of 120 nm is formed.

Further thereafter, the supply of trimethylaluminum is stopped, and then, by changing the flow rate of biscyclopentadienyl to 0.2 μmol/min and supplying the source material gases for 20 seconds, a contact layer made of p-type GaN having a thickness of 5 nm is formed.

### DESCRIPTION OF REFERENCE SIGNS

1: LED element
2A, 2B, 2C: Element for verification
5: Gap
11: Support substrate
13: Undoped semiconductor layer
14: Reflection electrode
15: n-type semiconductor layer
17: Light emitting layer
19: p-type semiconductor layer
20: LED layer
21: First electrode (transparent electrode)
23: Second electrode (transparent electrode)
24: Electroconductive light-transmitting material film
25: Power supply terminal
27: Power supply terminal
31: Reflection electrode
33: Reflection electrode
37: Bonding metal
39: Bonding metal
40: LED epi-layer
41: Substrate
45: Resist
50: LED layer
61: n-type semiconductor layer (n-type GaN layer)
63: First electrode (metal electrode)
90: LED element

1. An LED element comprising:
a first semiconductor layer constituted of n-type nitride semiconductor;
a light emitting layer constituted of nitride semiconductor where a bottom surface thereof is in contact with a portion of an upper surface of the first semiconductor layer;
a second semiconductor layer formed on the upper layer of the light emitting layer and constituted of p-type nitride semiconductor;
a first electrode constituted of a transparent electrode where a bottom surface thereof is in contact with a portion of an upper surface of the first semiconductor layer; and
a second electrode formed on the upper layer of the second semiconductor layer,
wherein at least a region of the first semiconductor layer, which region is in contact with the transparent electrode, is constituted of AlₙGa₁₋ₙN (0<n≦1) and has an n-type impurity concentration larger than 1×10¹⁹/cm³.

2. The LED element according to claim 1, wherein the second electrode is constituted of a transparent electrode formed on the upper layer of the second semiconductor layer.

3. The LED element according to claim 2, wherein a relationship of:
0.2≦S1/(S1+S2)≦0.3
is satisfied, assuming that an area of a contact region between the first electrode and the first semiconductor layer is S1 and that an area of a contact region between the second electrode and the second semiconductor layer is S2.

4. The LED element according to claim 1, wherein the light emitting layer and the first electrode are formed on top of the second semiconductor layer in a state in which the light emitting layer and the first electrode are spaced apart from each other with a gap as viewed in a horizontal direction.

5. The LED element according to any one of claim 2, wherein the light emitting layer and the first electrode are formed on top of the second semiconductor layer in a state in which the light emitting layer and the first electrode are spaced apart from each other with a gap as viewed in a horizontal direction.

6. The LED element according to any one of claim 3, wherein the light emitting layer and the first electrode are formed on top of the second semiconductor layer in a state in which the light emitting layer and the first electrode are spaced apart from each other with a gap as viewed in a horizontal direction.
